(19) United States
(12) Patent Application Publication
(10) Pub. No.: US 2012/0012174 A1
(43) Pub. Date: Jan. 19, 2012

(54) SOLAR CELL DEVICE HAVING AN AIRBRIDGE TYPE CONTACT

(75) Inventor: CHAN SHIN WU, Hukou Shiang (TW)

(73) Assignee: SOLAPOINT CORPORATION, Hukou Shiang (TW)

(21) Appl. No.: 13/037,202

(22) Filed: Feb. 28, 2011

(30) Foreign Application Priority Data
Jul. 14, 2010 (TW) 099123080
Jan. 31, 2011 (TW) 100103583

(51) Int. Cl. H01L 31/0224

(52) U.S. Cl. 136/256

(57) ABSTRACT

A solar cell device having an airbridge type contact and the method of forming the same are provided. The solar cell device includes a semiconductor layer for turning light into electric current; at least two conductive line sections for transmitting the electric current from the semiconductor layer and formed on the semiconductor layer; and an airbridge type contact interposing between the two conductive line sections and connecting thereto, wherein a space under the airbridge type contact and between the two conductive line sections is formed, and light is allowed to enter the semiconductor layer by passing through the space.

### RELATED APPLICATIONS

This application claims the right of priority based on Taiwan Patent Application No. 99123080, entitled “Solar Cell Device Having an Air-bridge Type Contact”, filed on Jul. 14, 2010 and Taiwan Patent Application No. 100103583, entitled “Solar Cell Device Having an Air-bridge Type Contact”, filed on Jan. 31, 2011. The entire contents of the aforementioned applications are incorporated herein by reference.

### FIELD OF THE INVENTION

The present invention relates to solar cell devices, and more particularly, to a solar cell device having an airbridge type contact.

### BACKGROUND OF THE INVENTION

In recent years, solar energy has become an important new type of energy source. Research on the development of solar energy is tremendously conducted on a global scale. Hitherto, numerous solar cells of different forms have been commercialized to enable mass production thereof and have become consumer products. Hence, ongoing improvement on solar cell technology is urgently required to meet the future need for the development of solar energy.

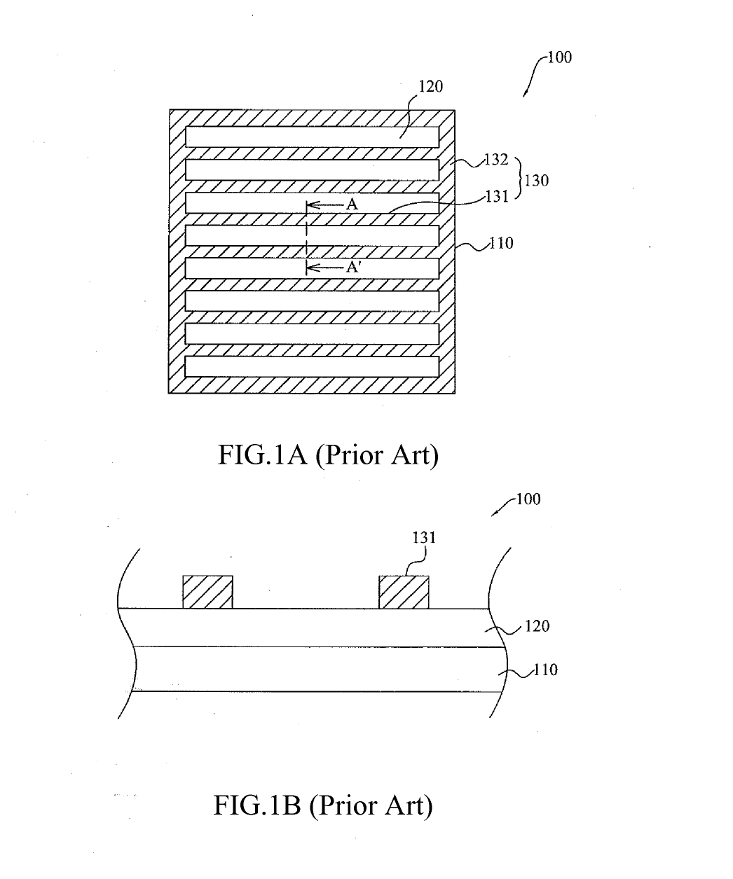

A solar cell device usually comprises a semiconductor layer with a p-n junction and a contact disposed on a front surface (i.e., a light-facing side) of the solar cell device for transmitting and collecting electric current generated by means of light absorption taking place in the semiconductor layer. The contact, which is typically of a grid-like pattern, comprises a plurality of parallel long wires and a bus disposed at the periphery of a chip structure and orthogonal to the wires. FIG. 1A is a top view of a light-facing side of a conventional solar cell device 100. FIG. 1B is a cross-sectional view of the solar cell device 100 taken along line A-A′ of FIG. 1A. As shown in FIGS. 1A and 1B, the solar cell device 100 comprises: a substrate 110; a semiconductor layer 120 connected to the substrate 110; and a contact layer 130 connected to the semiconductor layer 120 from above. The contact layer 130 comprises a plurality of parallel wires 131 and a bus 132. To collect electric current efficiently, the wires 131 are usually distributed across the surface of the semiconductor layer 120 and are in tight contact with the surface of the semiconductor layer 120. Hence, a portion of the semiconductor layer 120 is covered with the wires 131, and thus the wire-covered portion of the semiconductor layer 120 cannot absorb light. To increase the exposed area of the semiconductor layer 120, the line width of the wires 131 must be as small as possible. Also, to prevent an increase in resistance, the height of the wires 131 has to be increased accordingly. However, an increase in the height of the wires 131 causes an increase in the area of shade. Hence, the higher the wires 131 are, the more the oblique incident light is blocked.

The prior art provides plenty of structures and methods that are similar to the above and thus, inevitably, has various drawbacks. Therefore, it is imperative that the prior art should be supplemented with novel ideas that have inventiveness over the prior art.

### SUMMARY OF THE INVENTION

In view of various problems with the prior art, it is a feature of the present invention to provide a connection line having an airbridge. In other words, a line section of a contact wire is raised by an appropriate technique, such that an airbridge is formed from the gap between the raised line section and a semiconductor layer. Given the aforesaid structure, an exposed portion of the semiconductor layer is beneath the airbridge. The exposed portion of the semiconductor layer admits the oblique incident light, and thus enhances the performance of a solar cell device.

Another feature of the present invention is that a junction interface between the semiconductor layer and the contact wire is formed as a mushroom structure. In other words, the semiconductor layer comprises a neck portion connecting the contact wire, and the neck portion is narrowed by an appropriate technique to thereby increase the exposed portion of the semiconductor layer. The increased exposed portion of the semiconductor layer admits more oblique incident light, and thus enhances the performance of a solar cell device.

A solar cell device having an airbridge type contact according to an embodiment of the present invention comprising: a semiconductor layer for turning light into electric current; at least two conductive line sections for transmitting the electric current from the semiconductor layer and formed on the semiconductor layer; and an airbridge type contact electrically connecting the two conductive line sections, wherein a space under the airbridge type contact and between the two conductive line sections is formed, and light is allowed to pass through the space and enter the semiconductor layer.

The solar cell device having an airbridge type contact is provided according to another embodiment of the present invention, wherein the semiconductor layer further comprises a neck portion connecting one of the at least two conductive line sections, and wherein the neck portion with its connected conductive line section is formed as a mushroom structure.

Other aspects of the present invention solve other problems and are disclosed and illustrated in detail with the embodiments below together with the aforesaid aspects.

### BRIEF DESCRIPTION OF THE PICTURES

FIG. 1A (PRIOR ART) is a top view of a light-facing side of a conventional solar cell device;

FIG. 1B (PRIOR ART) is a cross-sectional view of the solar cell device taken along line A-A′ of FIG. 1A;

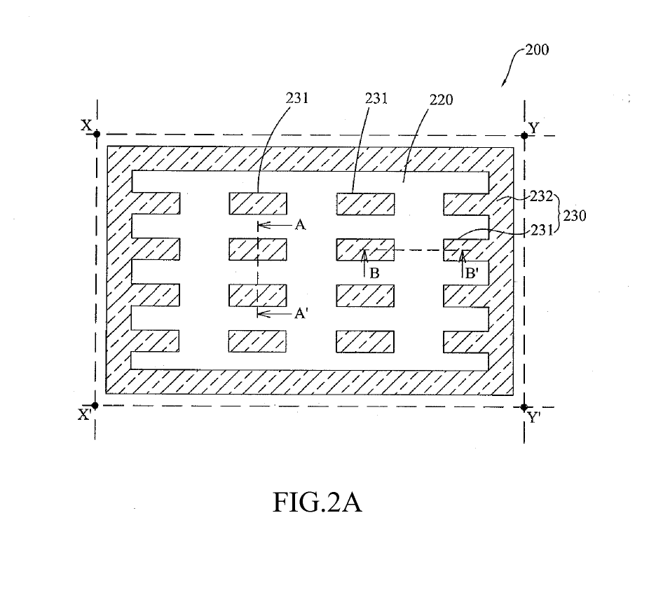

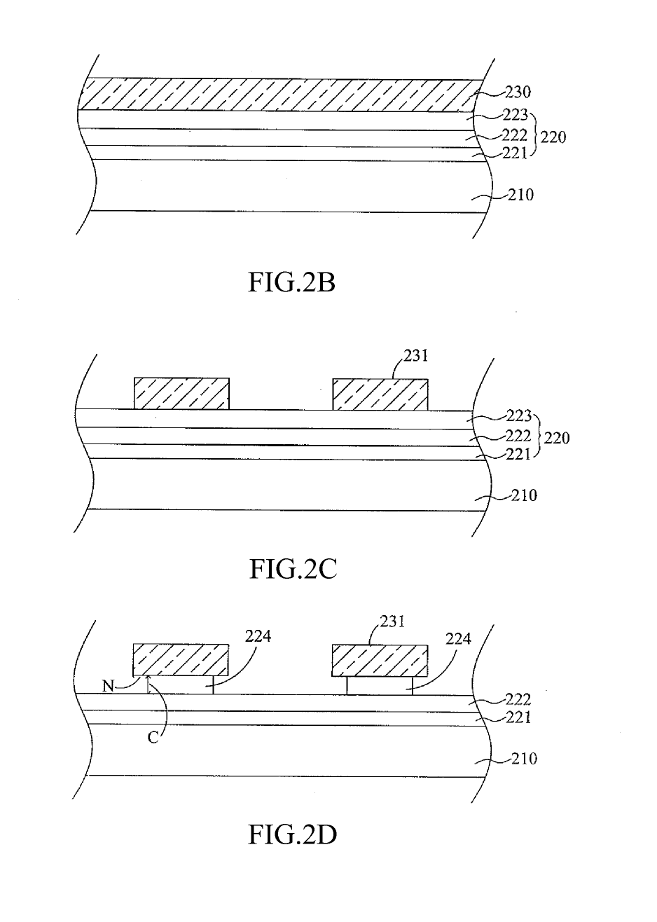

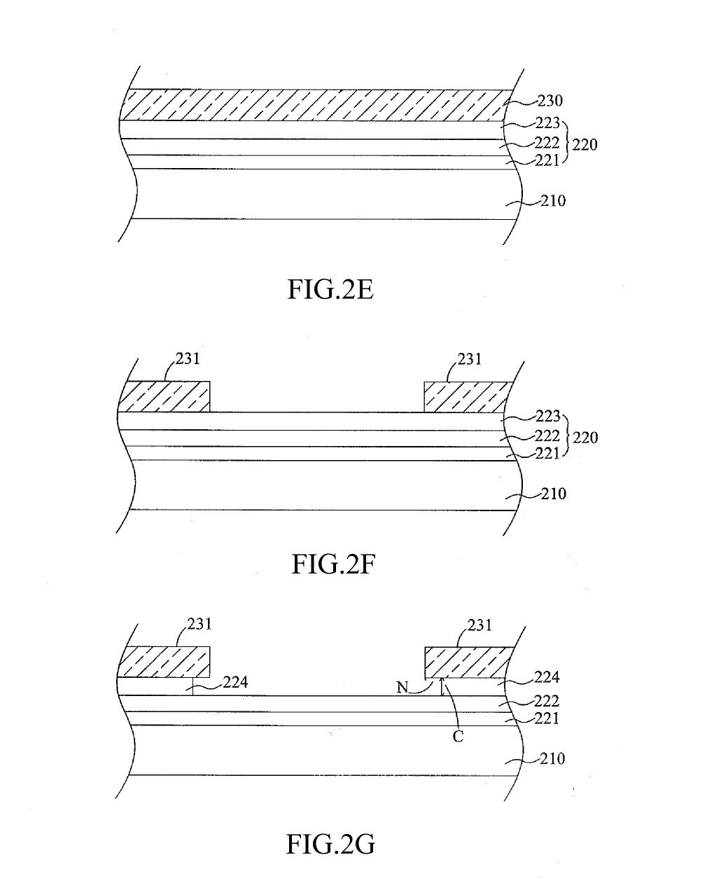

FIG. 2A is a top view of a semi-finished product of a solar cell device according to a first embodiment of the present invention;

FIG. 2B through FIG. 2G are cross-sectional views of a manufacturing process of the solar cell device of FIG. 2A;

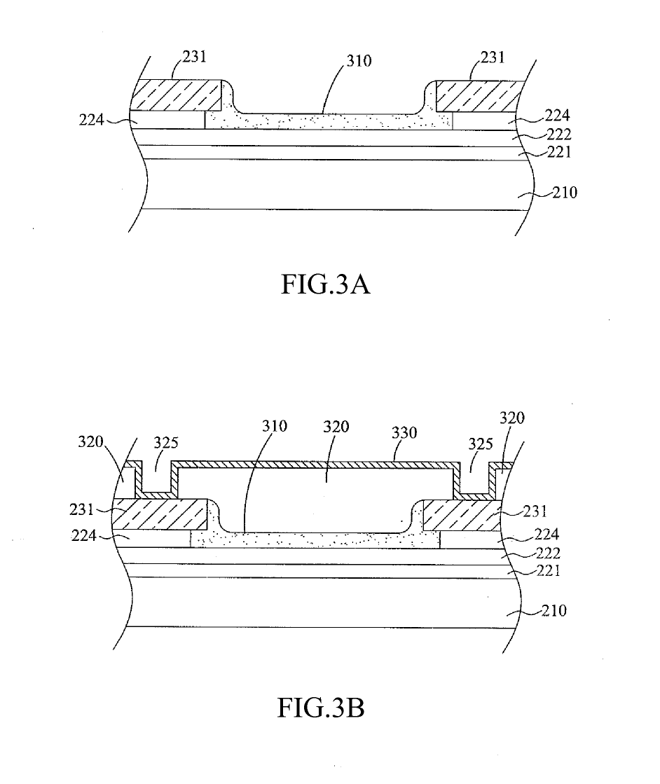

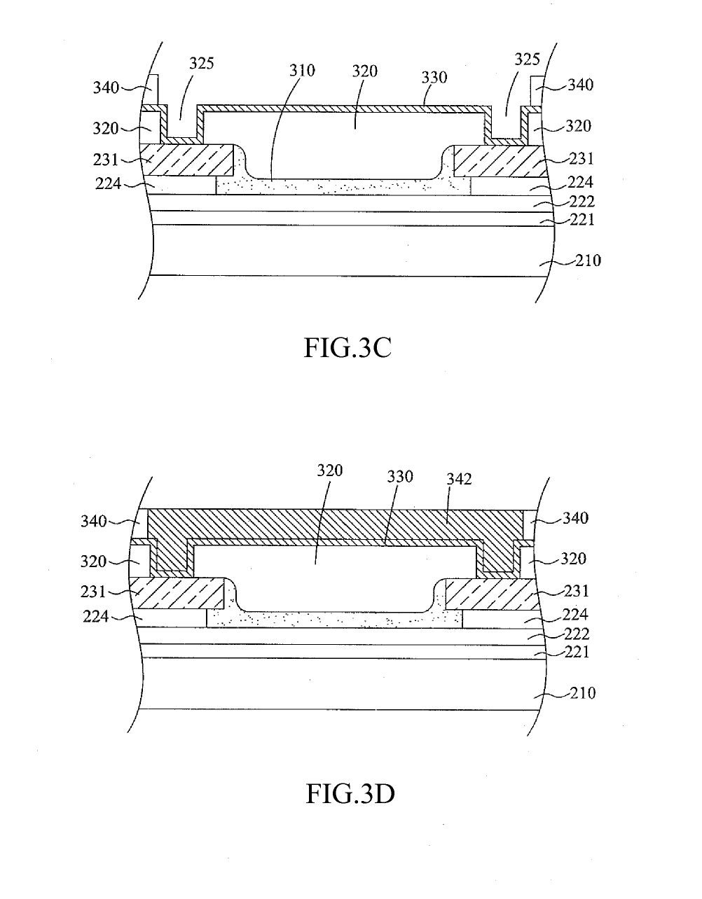

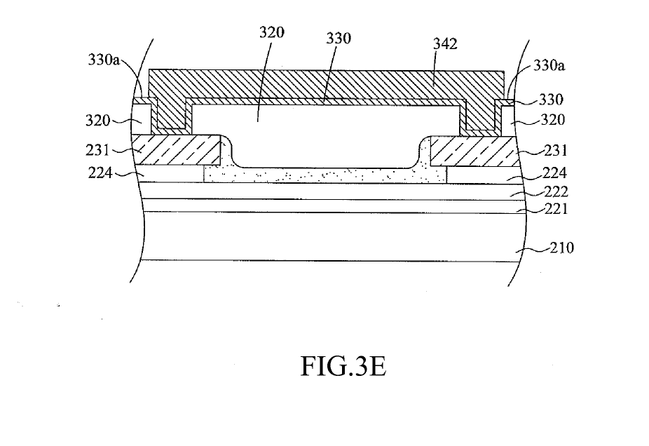

FIG. 3A through FIG. 3E are cross-sectional views of the manufacturing process of the solar cell device after FIG. 2G;

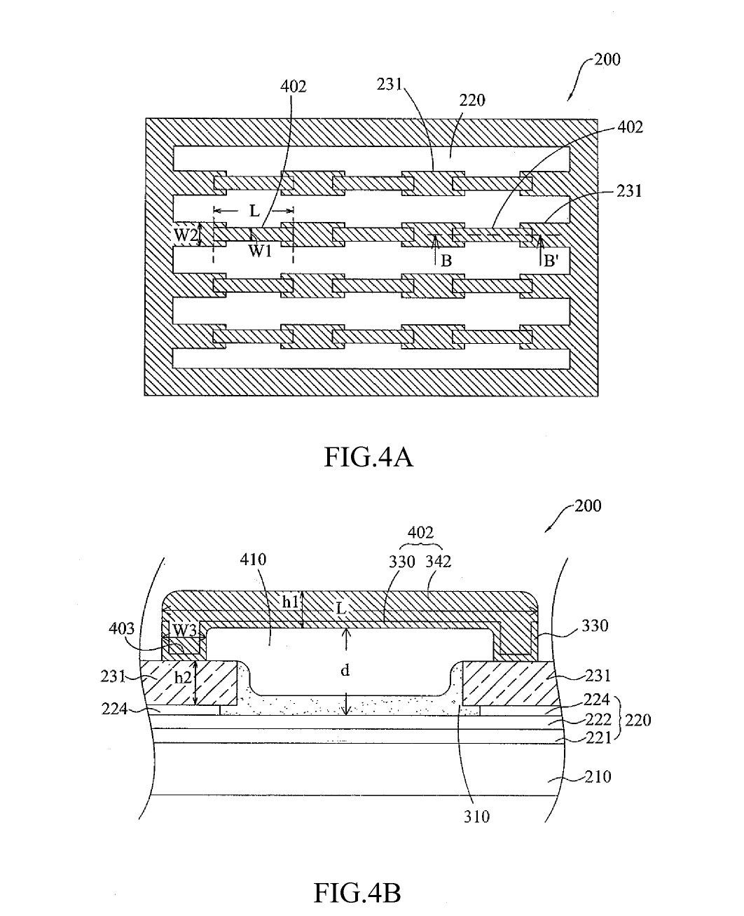

FIG. 4A is a top view of the solar cell device according to the first embodiment of the present invention;

FIG. 4B is a cross-sectional view of the solar cell device taken along line B-B′ of FIG. 4A;

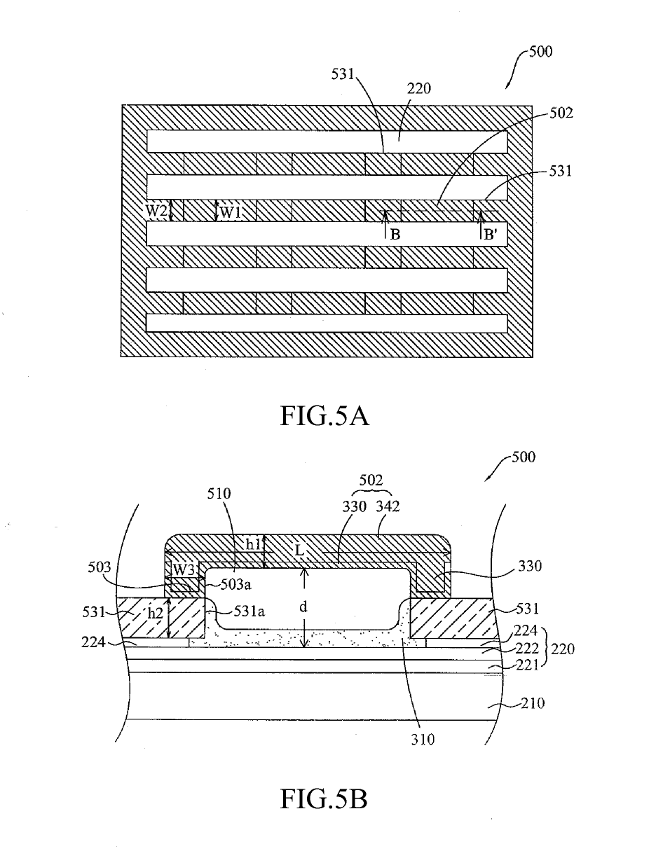

FIG. 5A is a top view of a solar cell device 500 according to a second embodiment of the present invention;

FIG. 5B is a cross-sectional view of the solar cell device taken along line B-B′ of FIG. 5A;

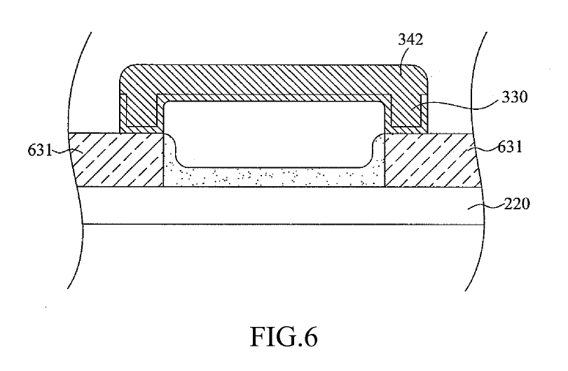

FIG. 6 is a cross-sectional view of a solar cell device 600 according to a third embodiment of the present invention; and

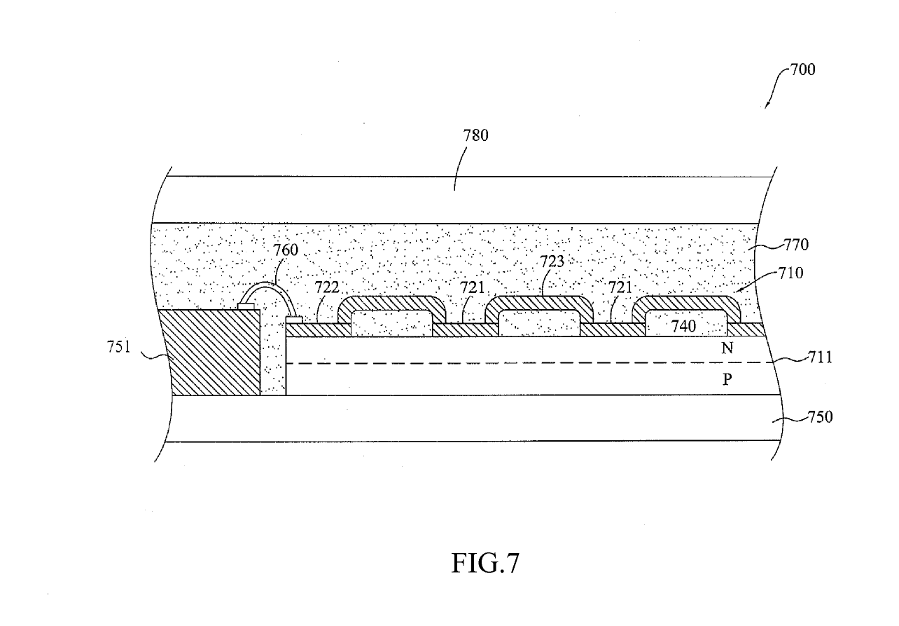

FIG. 7 is a cross-sectional view of a solar cell device 700 according to a fourth embodiment of the present invention.

### DETAILED DESCRIPTION OF THE INVENTION

The preferred embodiments of the present invention will now be described in greater details by referring to the drawings that accompany the present application. It should be noted that the features illustrated in the drawings are not necessarily drawn to scale. Descriptions of well-known components, materials, and process techniques are omitted so as to not unnecessarily obscure the embodiments of the invention.

FIG. 2A is a top view of a semi-finished product of a solar cell device 200 according to a first embodiment of the present invention. FIG. 2B through FIG. 2G are cross-sectional views of a manufacturing process of the solar cell device 200 of FIG. 2A.

As shown in FIG. 2A, in the first embodiment, the solar cell device 200 comprises a semiconductor layer 220 and a contact layer 230 disposed on the semiconductor layer 220. The semiconductor layer 220 is for use in fabricating one or more solar chips. Dashed lines X-X′ and Y-Y′ shown in FIG. 2A together define the area of fabrication of a single solar chip. The top-viewed profile of a single solar chip can be of different shapes, such as a rectangle shown in FIG. 2A. In other preferred embodiments of the present invention, the top-viewed profile of a single solar chip can be a square. The contact layer 230 comprises a plurality of conductive line sections 231 for transmitting the electric current. The plurality of conductive line sections 231 have a bus 232 for collecting the electric current from wires. With the solar cell device 200 being a semi-finished product, most of the conductive line sections 231 shown in FIG. 2A have not yet been connected to each other. To expose more area of the semiconductor layer and thereby receive more oblique incident light, it is necessary that the vertical junction interface between the contact layer 230 and the semiconductor layer 220 of the solar cell device 200 is formed as a mushroom structure by a process shown in cross-sectional views of FIG. 2B through FIG. 2D and FIG. 2E through FIG. 2G. FIGS. 2B through 2D are cross-sectional views of a manufacturing process of the solar cell device 200 taken along line A-A′ of FIG. 2A. FIGS. 2E through 2G are cross-sectional views of the manufacturing process of the solar cell device 200 taken along line B-B′ of FIG. 2A.

Referring to FIG. 2B and FIG. 2E, the manufacturing method of the solar cell device 200 comprises providing a substrate 210, forming the semiconductor layer 220 on the substrate 210, and forming the contact layer 230 on the semiconductor layer 220. The substrate 210 can be a growing substrate for the semiconductor layer 220, such as a GaAs substrate. In other embodiments, the substrate 210 can be a jointing substrate, such as a silicon substrate or other appropriate substrates. The semiconductor layer 220 can be a multilayer structure, comprises a IIIV group thin layer 221 having at least one p-n junction, and comprises a window layer 222 and a cover layer 223 on top of the thin layer 221. In this embodiment, the cover layer 223 is made of GaAs or InGaAs, and the window layer 222 is made of AlInP. In other embodiments, each of the sub-layers of the semiconductor layer 220 can be selectively made of a combination of appropriate ones of IIIV group elements in the periodic table. In a further embodiment, the substrate comprises a semiconductor layer and is exemplified by a silicon substrate, wherein an N-type upper layer and a P-type lower layer are formed in the silicon substrate when processed by a diffusion furnace. The materials described in this embodiment are proposed for an illustrative purpose only, as the present invention is not limited thereto. The contact layer 230 can be made of any appropriate metal, such as gold, aluminum, copper, silver, titanium, germanium, or an alloy thereof, and is preferably of a thickness between 10 μm and 30 μm.

However, referring to FIG. 2C and FIG. 2F, the plurality of conductive line sections 231 shown in FIG. 2A are formed by patterning the contact layer 230, using an appropriate technique. The plurality of conductive line sections 231 comprise the bus 232 (not shown in FIG. 2C and FIG. 2F). Afterward, referring to FIG. 2D and FIG. 2G, when the contact layer 230 thus patterned (that is, the conductive line sections 231 and/or the bus 232) is used as a mask, a portion of the cover layer 223 is removed by wet etching in a manner that at least a portion of the cover layer 223 is beneath the plurality of conductive line sections 231 and thus preserved. The purpose of this step is to expose the underlying window layer 222. During the wet etching process, the cover layer 223 under the conductive line sections 231 is undercut and narrowed inward by wet etching to form a neck portion denoted with reference numeral 224 as shown in FIG. 2D and FIG. 2G, thereby manifesting the aforesaid mushroom structure. Given the neck portion 224, the window layer 222 is exposed to a greater extent and thus admits more oblique incident light to thereby effectuate enhancement of the performance of the solar cell device 200. In this embodiment, the neck portion 224 is of a thickness C ranging between 0.6 μm and 0.8 μm, and the inward-narrowing distance N of the neck portion 224 is substantially equivalent to the thickness C of the neck portion 224. A point to note is that a structure similar to the neck portion can also be disposed beneath the bus 232.

FIG. 3A through FIG. 3E, FIG. 4A, and FIG. 4B are diagrams of the second half of the manufacturing process of the solar cell device 200 according to the first embodiment of the present invention. The second half of the manufacturing process is focused on formation of an airbridge in the direction B-B′; hence, all the cross-sectional views below show cross-sections which are taken in the direction B-B′.

Referring to FIG. 3A, upon completion of the structure shown in FIG. 2G, an anti-reflection layer 310 is formed above the substrate 210 to cover the portion of the window layer 222 exposed as a result of the aforesaid step. The anti-reflection layer 310 is made of SiN or any other appropriate material. Afterward, a portion of the anti-reflection layer 310 is removed by selective etching so as to expose the upper surface of the conductive line sections 231. Referring to FIG. 3B, a first patterning resist layer 320 is formed to cover the substrate 210 and expose at least a portion of the upper surface of the conductive line sections 231, so as to define contact openings 325 whereby the conductive line sections 231 are in connection with airbridges to be formed. The contact openings 325 total at least two and are positioned at the ends of the two adjacent conductive line sections 231 in the longitudinal direction B-B′, respectively. The first patterning resist layer 320 is made of any appropriate polymer or material, and is of a thickness adjustable according to the required height of the airbridges. Referring to FIG. 3B, a conformal conductive seed layer 330 is formed above the substrate 210 and on the surface of the first patterning resist layer 320 to cover the sidewall and the bottom of the contact openings 325; this step is performed by evaporation, sputtering, or any other appropriate technique. The conformal conductive seed layer 330 is made of gold, titanium, or an alloy thereof, and is of a thickness ranging between 500 Å and 1,000 Å, but the present invention is not limited thereto.

Then, referring to FIG. 3C, a second patterning resist layer 340 is formed to cover the substrate 210 in a manner that at least an airbridge-forming portion of the conformal conductive seed layer 330 remains exposed. For example, as shown in the drawing, the conformal conductive seed layer 330 covering the sidewall and the bottom of the two neighboring contact openings 325 in the longitudinal direction B-B′ is exposed, and the conformal conductive seed layer 330 on the first patterning resist layer 320 between the two neighboring contact openings 325 is also exposed. The second patterning resist layer 340 is made of any appropriate material. The first patterning resist layer 320 and the second patterning resist layer 340 are made of the same material or different materials, depending on a subsequent process.

Then, referring to FIG. 3D, a conductive layer 342 is formed on the exposed portions of the conformal conductive seed layer 330 shown in FIG. 3C. The conductive layer 342 is made of aluminum, copper, silver, titanium, germanium, or an alloy thereof. An electroplating process or any other appropriate process, such as evaporation or sputtering, performs the step. The conformal conductive seed layer 330 and the conductive layer 342 are made of the same material or different materials, depending on a subsequent process.

Then, referring to FIG. 3E, the second patterning resist layer 340 is removed by an appropriate etching process. The step is performed by an etching agent, which demonstrates higher selectivity for a photoresist material than for a metal. Afterward, an appropriate etching process is performed to remove a conformal conductive seed layer 330a which is otherwise exposed, using an etching agent which demonstrates higher selectivity for the conformal conductive seed layer 330a than for the conductive layer 342. Alternatively, the aforesaid appropriate etching process entails applying a patterning mask for protecting the conductive layer 342 and then removing the conformal conductive seed layer 330a which is otherwise exposed. After the conformal conductive seed layer 330a has been removed, the first patterning resist layer 320 is completely removed by an appropriate etching process. In this step, the first patterning resist layer 320 beneath the conformal conductive seed layer 330 and the conductive layer 342 and are also removed.

The aforesaid steps result in a structure shown in FIGS. 4A and 4B. FIG. 4A is a top view of the solar cell device 200 according to the first embodiment of the present invention. FIG. 4B is a cross-sectional view of the solar cell device 200 taken along line B-B′ of FIG. 4A. As shown in the drawings, the solar cell device 200 comprises: the substrate 210; the semiconductor layer 220 disposed on the substrate 210; at least two adjacent conductive line sections 231 disposed on the semiconductor layer 220; and an airbridge type contact 402 formed from both the conformal conductive seed layer 330 and the conductive layer 342 and configured to electrically connect with the two conductive line sections 231, wherein a space 410 under the airbridge type contact 402 and between the two conductive line sections 231 is formed, and light is allowed to pass through the space 410 and enter the semiconductor layer 220. Hence, the area of the semiconductor layer 220 under the airbridge type contact 402 is exposed and thus is able to admit oblique incident light, thereby enhancing the performance of the solar cell device 200. In another embodiment, a transparent layer is disposed in the space 410, and the transparent layer is in contact with the airbridge type contact 402 to support the airbridge type contact 402. The transparent layer is made of any material penetrable by light and thus effective in preserving the function of the airbridge type contact 402.

Referring to FIGS. 4A and 4B, the airbridge type contact 402 comprises a post 403 which is connected to one of the at least two conductive line sections 231. In this embodiment, the length L of the airbridge type contact 402 in the extension direction thereof is equal to seven times of the width (a top-viewed width W1 shown in the drawings) perpendicular to the aforesaid extension direction approximately. In this embodiment, the width W1 is 5-8 μm approximately, and the length L is 35-56 μm approximately. Also, the present invention is implemented by various embodiments in which the L:W1 ratio is less than or equal to eight. It is well known that the exposed area of the semiconductor layer 220 increases with the quantity of the airbridge type contacts 402 of the solar cell device 200. Despite the above knowledge, persons skilled in the art should also give considerations to the required connection/contact area between the semiconductor layer 220 and the conductive line sections 231 in order to figure out the optimal exposed area and electric current collection efficiency. Furthermore, in this embodiment, the maximum vertical height d of the space 410 from the semiconductor layer 220 to the airbridge type contact 402 ranges between 5 μm and 15 μm. The height of the airbridge type contact 402 can be controlled by means of the height of a photoresist layer in the process. During the process, the thicker the photoresist layer is, the more the airbridge type contact 402 bends as shown in the drawings. FIG. 4A shows that, in this embodiment, a top-viewed width W2 of the conductive line sections 231 is larger than the top-viewed width W1 of the airbridge type contact 402, but the present invention is not limited thereto. In other embodiments, the top-viewed width W2 of the conductive line sections 231 is substantially equal to or less than the top-viewed width W1 of the airbridge type contact 402. The airbridge type contact 402 is of a thickness h1 ranging between 5 μm and 8 μm. The conductive line sections 231 are of a thickness h2 ranging between 5 μm and 8 μm. Furthermore, the post 403 of the airbridge type contact 402 is of a width W3 in the extension direction of the airbridge type contact 402. In a preferred embodiment, the width W3 is substantially equal to a thickness h2 of the conductive line sections 231. In another preferred embodiment, the thickness h1 is substantially equal to the thickness h2.

FIGS. 5A and 5B are diagrams of a solar cell device 500 according to the second embodiment of the present invention, respectively. FIG. 5A is a top view of the solar cell device 500 according to the second embodiment of the present invention. FIG. 5B is a cross-sectional view of the solar cell device 500 taken along line B-B′ of FIG. 5A. The second embodiment differs from the first embodiment in that, in the second embodiment, the top-viewed width W2 of conductive line sections 531 of the solar cell device 500 is preferably equal to the top-viewed width W1 of an airbridge type contact 502. Persons skilled in the art through optimization of alignment precision to circumvent limitations of a process can achieve the aforesaid objective. In the embodiments of the present invention, due to process limitations, the substantial equation between the top-viewed width W2 and the top-viewed width W1 allows an error of no greater than 1 μm.

Furthermore, a post 503 of the airbridge type contact 502 has a wall surface 503a facing a space 510 through which light passes. The conductive line sections 531 under the wall surface 503a have a wall surface 531 a facing the space 510 through which light passes. The wall surface 503a is substantially flush with the wall surface 531a. Likewise, the aforesaid feature “being substantially flush” allows an error of no greater than 1 μm. The width W3 is substantially equal to the thickness h2 of the conductive line sections 231 with an error of no greater than 1 μm. In this embodiment, the width W3 of the post 503 in the extension direction of the airbridge type contact 502, the thickness h1 of the airbridge type contact 502, and the thickness h2 of the conductive line sections 531 are substantially equal, with an error of no greater than 1 μm.

FIG. 6 is a cross-sectional view of a solar cell device 600 according to a third embodiment of the present invention. The third embodiment differs from the aforesaid embodiments in that, in the third embodiment, the junction interface between the uppermost portion of the semiconductor layer 220 and conductive line sections 631 is not significantly formed as a mushroom structure.

FIG. 7 is a cross-sectional view of a solar cell device 700 according to a fourth embodiment of the present invention. As shown in FIG. 7, the solar cell device 700 comprises: a solar chip 710; a carrying substrate 750 for carrying the solar chip 710; a transparent protective layer 770 for covering the solar chip 710; and a glass topping panel 780 for covering all the aforesaid elements. The solar chip 710 is electrically connected to a circuit 751 of the carrying substrate 750 via a lead 760. The solar chip 710 comprises a semiconductor layer 711 and a grid-like contact layer disposed thereon. The semiconductor layer 711 is made of any appropriate material. In this embodiment, the semiconductor layer 711 is a silicon substrate and has a p-n junction for doping and diffusion. The grid-like contact layer comprises at least two adjacent conductive line sections 721 on the semiconductor layer 711. The conductive line sections 721 comprise a peripherally-disposed bus 722. The grid-like contact layer further comprises an airbridge type contact 723 connected to the at least two adjacent conductive line sections 721. A space 740 is formed under the airbridge type contact 723. A portion of the transparent protective layer 770 fills the space 740 to support the airbridge type contact 723. The transparent protective layer 770 is made of a material penetrable by light, such as silica gel. Upon completion of fabrication of the grid-like contact layer (as disclosed in the aforesaid embodiments) and the lead 760, the silica gel and/or any other appropriate ingredient are evenly mixed to form a resultant material for making the transparent protective layer 770, and then the resultant material is applied to the solar chip 710. Afterward, the transparent protective layer 770 is covered with the glass topping panel 780, and then treated with a vacuum-suction process, such that the resultant material of the transparent protective layer 770 enters the space 740. Finally, the transparent protective layer 770 is finalized by being heated and cured.

The foregoing preferred embodiments are provided to illustrate and disclose the technical features of the present invention, and are not intended to be restrictive of the scope of the present invention. Hence, all equivalent variations or modifications made to the foregoing embodiments without departing from the spirit embodied in the disclosure of the present invention should fall within the scope of the present invention as set forth in the appended claims.

1. A solar cell device having an airbridge type contact, the solar cell device comprising:
a semiconductor layer for turning light into electric current;
at least two conductive line sections for transmitting the electric current from the semiconductor layer and formed on the semiconductor layer; and
an airbridge type contact electrically connecting the two conductive line sections, wherein a space under the airbridge type contact and between the two conductive line sections is formed, and light is allowed to pass through the space and enter the semiconductor layer.

2. The solar cell device as claim 1, wherein the semiconductor layer further comprises a neck portion connecting one of the at least two conductive line sections, and wherein the neck portion with its connected conductive line section is formed as a mushroom structure.

3. The solar cell device as claim 1, wherein the airbridge type contact is formed with a post connecting one of the at least two conductive line sections, the airbridge type contact has a length in an alignment direction of the two conductive line sections, and the post has a top-viewed width vertical to the alignment direction, wherein the length of the airbridge type contact is less than or equal to eight times of the top-viewed width of the post.

4. The solar cell device as claim 1, wherein the space has a maximum vertical height between 5 μm and 15 μm from the semiconductor layer to the airbridge type contact.

5. The solar cell device as claim 1, wherein the airbridge type contact is substantially as thick as one of the at least two conductive line sections.

6. The solar cell device as claim 1, wherein the airbridge contact has a first top-viewed width and one of the at least two conductive line section has a second top-viewed width, the first top-viewed width and the second top-viewed width being vertical to an alignment direction of the two conductive line sections, wherein the first top-viewed width is substantially the same as the second top-viewed width.

7. The solar cell device as claim 1, wherein the space is filled with a transparent material.
